(19) United States
(12) Patent Application Publication
(10) Pub. No.: US 2017/0040506 A1
(43) Pub. Date: Feb. 9, 2017

(54) LIGHT-EMITTING APPARATUS AND ILLUMINATION APPARATUS

(71) Applicant: Panasonic Intellectual Property Management Co., Ltd., Osaka (JP)

(72) Inventors: Masumi ABE, Osaka (JP); Naoki TAGAMI, Miyagi (JP); Yasuharu UENO, Osaka (JP); Ryoji YOKOTANI, Osaka (JP); Toshiaki KURACHI, Kyoto (JP)

(21) Appl. No.: 15/223,833

(22) Filed: Jul. 29, 2016

(30) Foreign Application Priority Data
Aug. 3, 2015 (JP) 2015-153609

(51) Int. Cl. H01L 33/50; F21S 8/02; H01L 33/56

(52) U.S. Cl. CPC H01L 33/507; H01L 33/56; F21S 8/026; F21Y 2115/10

(57) ABSTRACT

A light-emitting apparatus includes: a substrate; an LED chip disposed on the substrate; and a sealing member that contains a yellow phosphor and a cerium oxide, and seals the LED chip. An amount of the cerium oxide contained in the sealing member depends on a peak wavelength of a light emission spectrum of the LED chip, and when the peak wavelength of the light emission, spectrum of the LED chip is 470 nm or less, the amount of the cerium oxide contained in the sealing member is 0.100 wt % or less.

### CROSS REFERENCE TO RELATED APPLICATION

This application claims the benefit of priority of Japanese Patent Application Number 2015-153609 filed on Aug. 3, 2015, the entire content of which is hereby incorporated by reference.

### BACKGROUND

1. Technical Field

The present disclosure relates to a light-emitting apparatus and an illumination apparatus including the light-emitting apparatus.

2. Description of the Related Art

A COB (chip-on-board) light-emitting apparatus (light-emitting-module) is conventionally known in which an LED (light-emitting diode) chip mounted on a substrate is sealed with a sealing member formed of a resin containing a phosphor (for example, see Japanese Unexamined Patent Application Publication No. 2011-146640).

### SUMMARY

There are cases where a cerium oxide is added to the sealing member in order to reduce the occurrence of oxidation and degradation of the sealing member in the COB light-emitting apparatus. Cerium oxides have the property of absorbing light mainly in the ultraviolet range, and generates heat by absorbing such light. Such heat generation may cause a failure of the LED chip. Thus, a goal for the above light-emitting apparatus is to reduce the effect heat generated by the cerium oxide has on the LED chip.

In view of this, the present disclosure provides a light-emitting apparatus and an illumination apparatus that are capable of reducing the effect heat generated by a cerium oxide contained in a sealing member has on an LED chip.

A light-emitting apparatus according to an aspect of the present disclosure includes: a substrate; a light-emitting element disposed on the substrate; and a sealing member that contains a phosphor and a cerium oxide, and seals the light-emitting element, wherein an amount of the cerium oxide contained in the sealing member depends on a peak wavelength of a light emission spectrum of the light-emitting element, and when the peak wavelength of the light emission spectrum of the light-emitting element is 470 nm or less, the amount of the cerium oxide contained in the sealing member is 0.100 wt % or less.

A light-emitting apparatus according to an aspect of the present disclosure includes: a substrate; a light-emitting element disposed on the substrate; and a sealing member that contains a phosphor and a cerium oxide, and seals the light-emitting element, wherein the sealing member includes: a first sealing layer that seals the light-emitting element; and a second sealing layer provided above the first sealing layer, and an amount of the cerium oxide contained in the second sealing layer is greater than an amount of the cerium oxide contained in first sealing layer.

An illumination apparatus according to an aspect of the present disclosure includes: the light-emitting apparatus according to any of the above aspects; and a lighting apparatus that supplies the light-emitting apparatus with electric power for lighting the light-emitting apparatus.

The light-emitting apparatus and the illumination apparatus according to an aspect of the present disclosure are capable of reducing the effect heat generated by the cerium oxide has on the LED.

### BRIEF DESCRIPTION OF DRAWINGS

The figures depict one or more implementations in accordance with the present teaching, by way of examples only, not by way of limitations. In the figures, like reference numerals refer to the same or similar elements.

FIG. 1 is a perspective view of an external appearance of a light-emitting apparatus according to Embodiment 1;

FIG. 2 is a plan view of a light-emitting apparatus according to Embodiment 1;

FIG. 3 is a plan view illustrating the internal structure of a light-emitting apparatus according to Embodiment 1;

FIG. 4 is a schematic cross-sectional view of a light-emitting apparatus, taken along line IV-IV in FIG. 2;

FIG. 5 illustrates a spectral transmittance of a silicone resin containing a cerium oxide;

FIG. 6 is a first graph showing a spectral transmittance of a silicone resin depending on the presence and absence of a cerium oxide, and a light emission spectrum of an LED chip having a center wavelength of 450 nm;

FIG. 7 is a second graph showing a spectral transmittance of a silicone resin depending on the presence and absence of a cerium oxide, and a light emission spectrum of an LED chip having a center wavelength of 450 nm;

FIG. 8 is for illustrating an environment of the experiment concerning a cerium oxide content;

FIG. 9 illustrates the results of the experiment concerning a cerium oxide content;

FIG. 10 illustrates the relationship between the cerium oxide content and the light transmittance of a resin plate;

FIG. 11 illustrates the relationship between the cerium oxide content and the temperature of a resin plate;

FIG. 12 is a schematic cross-sectional view of a light-emitting apparatus according to Embodiment 2;

FIG. 13 schematically illustrates a structure of a first sealing layer;

FIG. 14 schematically illustrates a structure of a second sealing layer;

FIG. 15 is a flowchart of a method of manufacturing a light-emitting apparatus according to Embodiment 2;

FIG. 16A is a first schematic cross-sectional view illustrating a method of manufacturing a light-emitting apparatus according to Embodiment 2;

FIG. 16B is a second schematic cross-sectional view illustrating a method of manufacturing a light-emitting apparatus according to Embodiment 2;

FIG. 16C is a third schematic cross-sectional view illustrating a method of manufacturing a light-emitting apparatus according to Embodiment 2;

FIG. 16D is a fourth schematic cross-sectional view illustrating a method of manufacturing a light-emitting apparatus according to Embodiment 2;

FIG. 17 is a cross-sectional view of an illumination apparatus according to Embodiment 3; and

FIG. 18 is a perspective view of external appearances of an illumination apparatus and peripheral members thereof according to Embodiment 3.

### DETAILED DESCRIPTION OF THE EMBODIMENTS

Hereinafter, a light-emitting apparatus, etc., according to embodiments are described with reference to the Drawings. Note that each of the embodiments described below shows a general or specific example. The numerical values, shapes, materials, structural elements, the arrangement and connection of the structural elements, steps, the processing order of the steps, etc., shown in the following embodiments are mere examples, and are not intended to limit the scope of the present disclosure. As such, among the structural elements in the following embodiments, those not recited in any one of the independent claims which indicate the broadest inventive concepts are described as arbitrary structural elements.

Furthermore, the respective figures are schematic illustrations and are not necessarily precise illustrations. Additionally, substantially identical elements are assigned the same reference signs, and there are cases where overlapping descriptions are omitted or simplified.

### Embodiment 1

### Configuration of Light-Emitting Apparatus

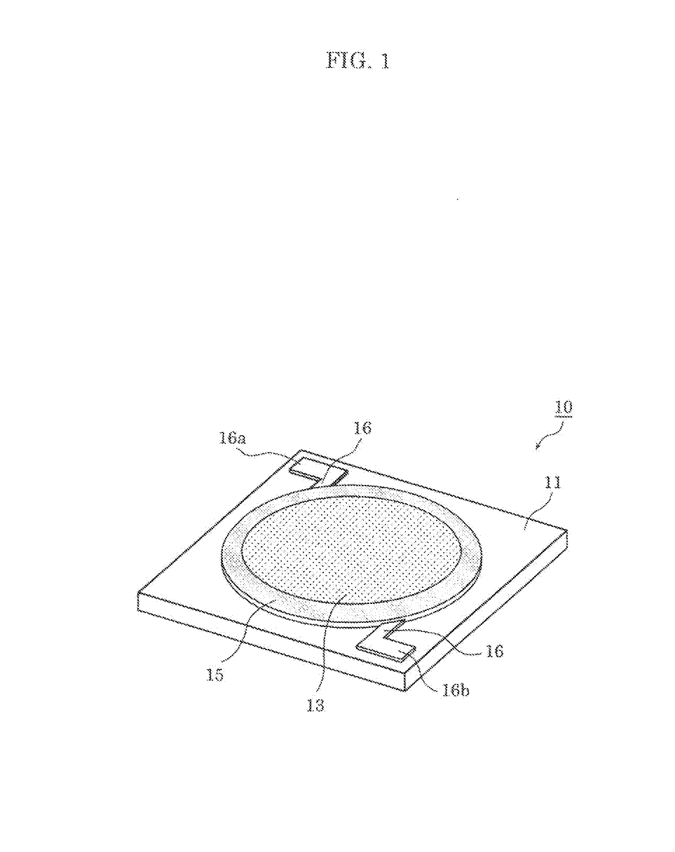

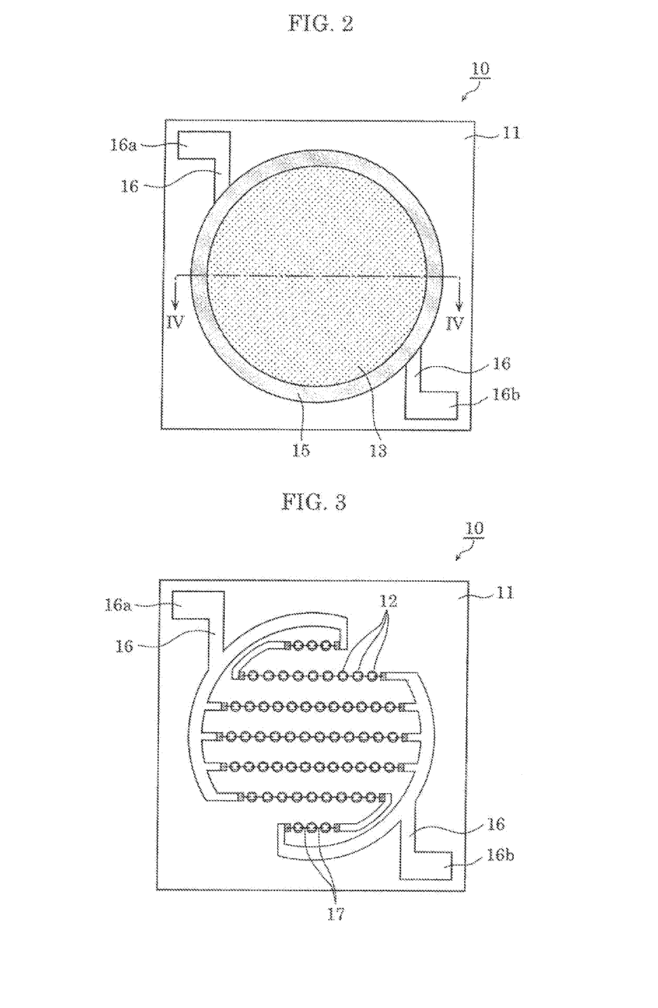

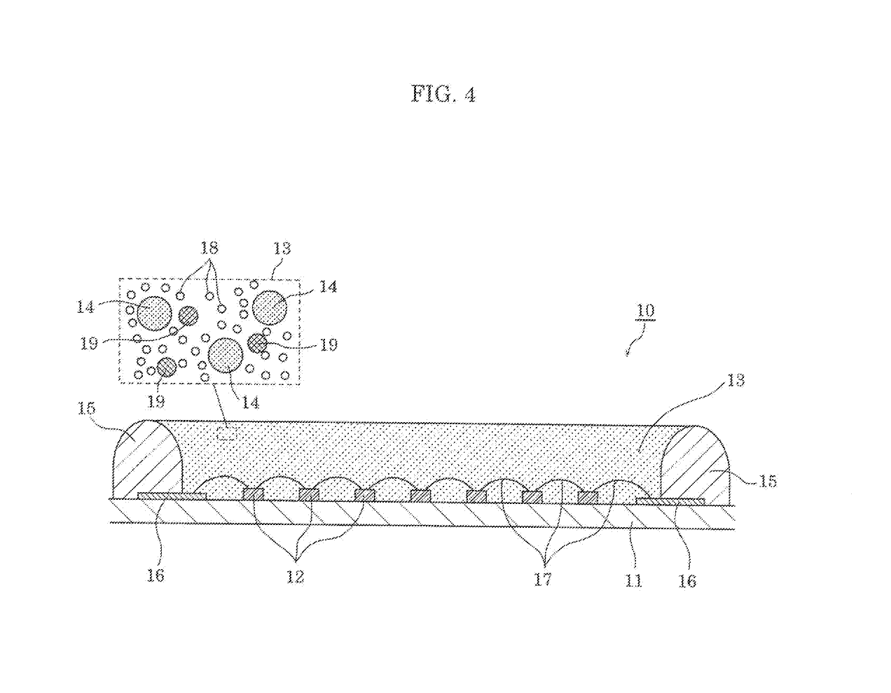

First, the configuration of the light-emitting, apparatus according to Embodiment 1 will be described with reference to the Drawings. FIG. 1 is a perspective view of an external appearance of a light-emitting apparatus according to Embodiment 1. FIG. 2 is a plan view of a light-emitting apparatus according to Embodiment 1. FIG. 3 is a plan view illustrating the internal structure of a light-emitting apparatus according to Embodiment 1. FIG. 4 is a schematic cross-sectional view of a light-emitting apparatus, taken along line IV-IV in FIG. 2. Note that the above-mentioned FIG. 3 is a plan view of the light-emitting apparatus which corresponds to that illustrated in FIG. 2 and illustrates the internal structure thereof including the arrangement of LED chips 12 and a wiring pattern with sealing member 13 and dam member 15 removed. It should also be noted that since FIG. 4 is a schematic cross-sectional view, FIG. 4 does not completely match FIG. 2 in terms of the number of LED chips 12 and so on.

Light-emitting apparatus 10 according to Embodiment 1 includes substrate 11, two or more LED chips 12, sealing member 13, and dam member 15 as illustrated in FIG. 1 to FIG. 4.

Light-emitting apparatus 10 is what is called a COB LED module in which LED chips 12 axe directly mounted on substrate 11.

Substrate 11 has a wiring region on which wiring 16 is provided. Note that wiring 16 (together with electrode 16a and electrode 16b) is formed of a metal for supplying electric power to LED chips 12. Substrate 11 is, for example, a metal-based substrate or a ceramic substrate. Furthermore, substrate 11 may be a resin substrate that uses a resin as a base material.

An alumina substrate made of aluminum oxide (alumina), an aluminum nitride substrate made of aluminum nitride, or the like is used as the ceramic substrate. An aluminum alloy substrate, an iron alloy substrate, a copper alloy substrate, or the like, the surface of which is coated with an insulating film, for example, is used as the metal-based substrate. A glass-epoxy substrate made of glass fiber and an epoxy resin is used as the resin substrate, for example.

Note that a substrate having a high optical reflectivity (e.g., an optical reflectivity of 90% or higher), for example, may be used as substrate 11. Using a substrate having a high optical reflectivity as substrate 11 allows light emitted by LED chips 12 to be reflected off the surface of substrate 11. This results in an increase in the light extraction rate of light-emitting apparatus 10. Examples of the substrate include a white ceramic substrate that uses alumina, as a base material.

Alternatively, a light-transmissive substrate having high light transmittance may be used as substrate 11. Examples of the substrate include a light-transmissive ceramic substrate made of polycrystalline alumina or aluminum nitride, a clear glass substrate made of glass, a crystal substrate made of crystal, a sapphire substrate made of sapphire, or a transparent resin substrate made of a transparent resin material.

Note that substrate 11 has a rectangular shape in Embodiment 1, but may have a circular or other shape.

LED chip 12 is one example of the light-emitting element and is a blue LED chip which emits blue light. For example, a gallium nitride LED chip formed using an InGaN-based material and having a central wavelength (a peak wavelength of the light emission spectrum) in the range from 430 nm to 470 nm is used as LED chip 12.

Note that instead of LED chip 12, LED chip having a peak wavelength of the light emission spectrum in the range from 365 nm to 425 nm (hereinafter referred to as a violet LED chip) may be used in light-emitting apparatus 10.

A plurality of light-emitting element lines including two or more LED chips 12 are provided on substrate 11. From the structural perspective, seven light-emitting element lines are provided on substrate 11 in such a way as to be fit within the shape of a circle as illustrated in FIG. 3.

From the electrical perspective, five light-emitting element lines each including 12 LED chips 12 connected in series are provided on substrate 11. These five light-emitting element lines are connected in parallel and emit light with electric power supplied between electrode 16a and electrode 16b.

As shown schematically in FIG. 4, LED chips 12 are connected to each other in series in a chip-to-chip configuration mainly by bonding wire 17 (some of LED chips 12 are connected by wiring 16). Bonding wire 17 is a power supply wire connected to LED chips 12. For example, gold (An), silver (Ag), copper (Cu), or the like is used as a metal material of bonding wire 17 as well as a metal material of wiring 16, electrode 16a, and electrode 16b mentioned above.

Dam member 15 is provided on substrate 11 and serves to block sealing member 13. For example, a thermosetting resin or a thermoplastic resin having an insulating property is used as dam member 15. More specifically, a silicone resin, a phenol resin, an epoxy resin, a BT (bismaleimide-triazine) resin, PPA (polyphthalamide), or the like is used as dam member 15.

It is desirable that dam member 15 have a light-reflecting property in order to increase the light extraction rate of light-emitting apparatus 10. Thus, a resin in a white color (what is called a white resin) is used as dam member 15 in Embodiment 1. Note that in order to increase the light-reflecting property of dam member 15, TiO₂, Al₂O₃, ZrO₂, MgO, and the like particles may be contained in dam member 15.

In light-emitting apparatus 10, dam member 15 is formed in a circular annular shape so as to surround two or more LED chips 12 in a top view. Sealing member 13 is provided in a region surrounded by dam member 15. The outer shape of dam member 15 may be a rectangular annular shape.

Sealing member 13 contains yellow phosphor 14, filler 18, and cerium oxide 19 (which are illustrated in FIG. 4), and seals two or more LED chips 12. More specifically, sealing member 13 seals two or more LED chips 12, bonding wire 17, and part of wiring 16. The base material for sealing member 13 is a light-transmissive resin material. As the light-transmissive resin material, a methyl-based silicone resin is used, for example, but an epoxy resin, a urea resin, or the like may be used. Sealing member 13 has a thickness of about 0.7 mm.

Sealing member 13 is characterized by containing cerium oxide 19, the amount of which depends on a peak wavelength of a light emission spectrum of LED chip 12. Specifically the amount of cerium oxide 19 contained in sealing member 13 is 0.10 wt % or less when the peak wavelength of LED chip 12 in the light emission spectrum is 470 nm or less.

Yellow phosphor 14 is one example of a phosphor (phosphor particles) and is excited by the light emitted from LED chip 12 and produces yellow fluorescence. For example, an yttrium aluminum garnet (YAG)-based phosphor is used as yellow phosphor 14.

In this configuration, the wavelength of a portion of the blue light emitted from LED chips 12 is converted by yellow phosphor 14 contained in sealing member 13, so that the portion is transformed into yellow light. Then, the blue light not absorbed by yellow phosphor 14 and the yellow light resulting from the wavelength conversion by yellow phosphor 14 are diffused and mixed within sealing member 13. Consequently, white light is emitted from sealing member 13.

Filler 18 is silica having an average grain size of about 10 nm, for example, and may be a different material. In sealing member 13, yellow phosphor 14 less easily sinks due to filler 18 serving as a resistor. Therefore, yellow phosphor 14 is dispersed in sealing member 13. Furthermore, filler 18 also has a function of diffusing the light emitted from LED chip 12. Note that filler 18 is not essential and not required to be contained in sealing member 13.

Cerium oxide 19 is, for example, a powdery cerium oxide having an average grain size of 36 nm. Cerium oxide 19 has the function of storing oxygen and the property of being chemically bonded to SiO, and is used as a substance that prevents oxidation and degradation of sealing member 13.

Note that FIG. 4 is a schematic illustration; the shapes, grain sixes, etc., of yellow phosphor 14, filler 18, and cerium oxide 19 illustrated in FIG. 4 are schematic and not precise.

### Properties of Cerium Oxide

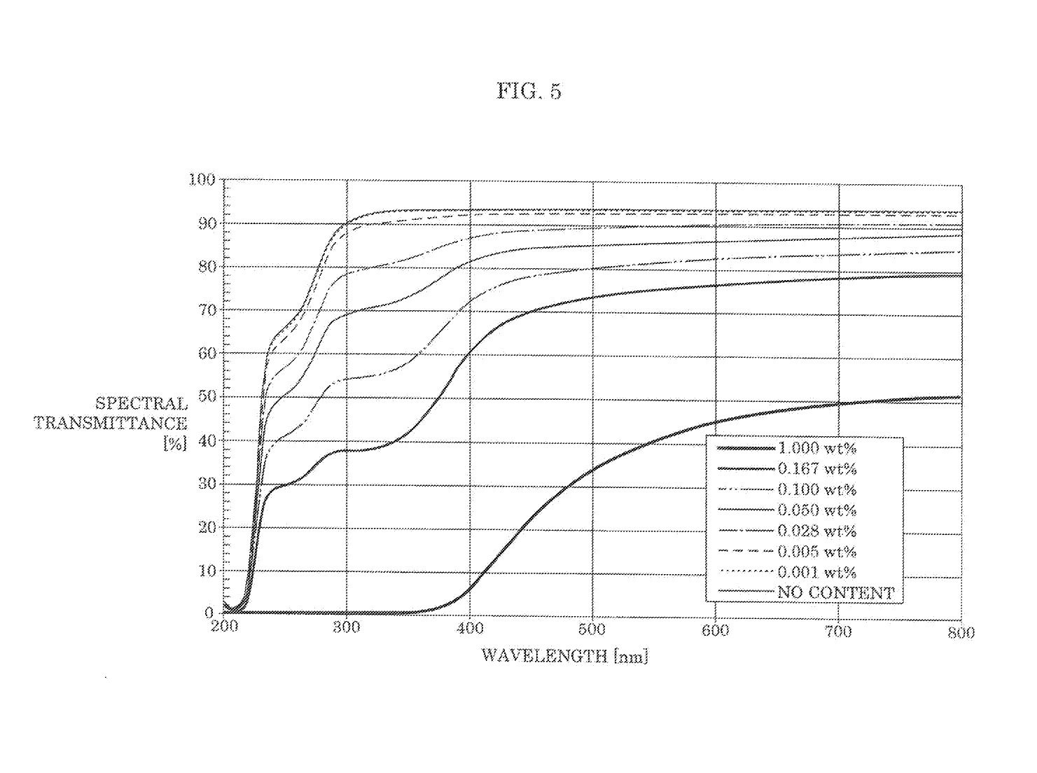

Next, properties of cerium oxide 19 are described. FIG. 5 illustrates a spectral transmittance of a silicone resin containing cerium oxide 19. In FIG. 5, graphs of silicone resins containing different amounts of oxide cerium 19 are plotted. Specifically, the amounts of cerium oxide 19 in the graphs illustrated in FIG. 5 are 1.00 wt %, 0.167 wt %, 0.100 wt %, 0.050 wt %, 0.028 wt %, 0.005 wt %, 0.001 wt %, and 0 wt % (no content) of the silicone resin. Note that the amount of cerium oxide 19 contained in sealing member 13 being 1.00 wt % means that there is 1 unit weight of cerium oxide 19 for every 100 unit weight of silicone resin, which is a base material of sealing member 13.

Cerium oxide 19 has the property of absorbing light in the ultraviolet range as illustrated in FIG. 5. The wavelength range of light that cerium oxide 19 absorbs reaches at least about 400 nm. Since a component having a wavelength of about 400 nm is contained in LED chip 12 of light-emitting apparatus 10, a portion of the light emitted from LED chips 12 is absorbed by cerium oxide 19.

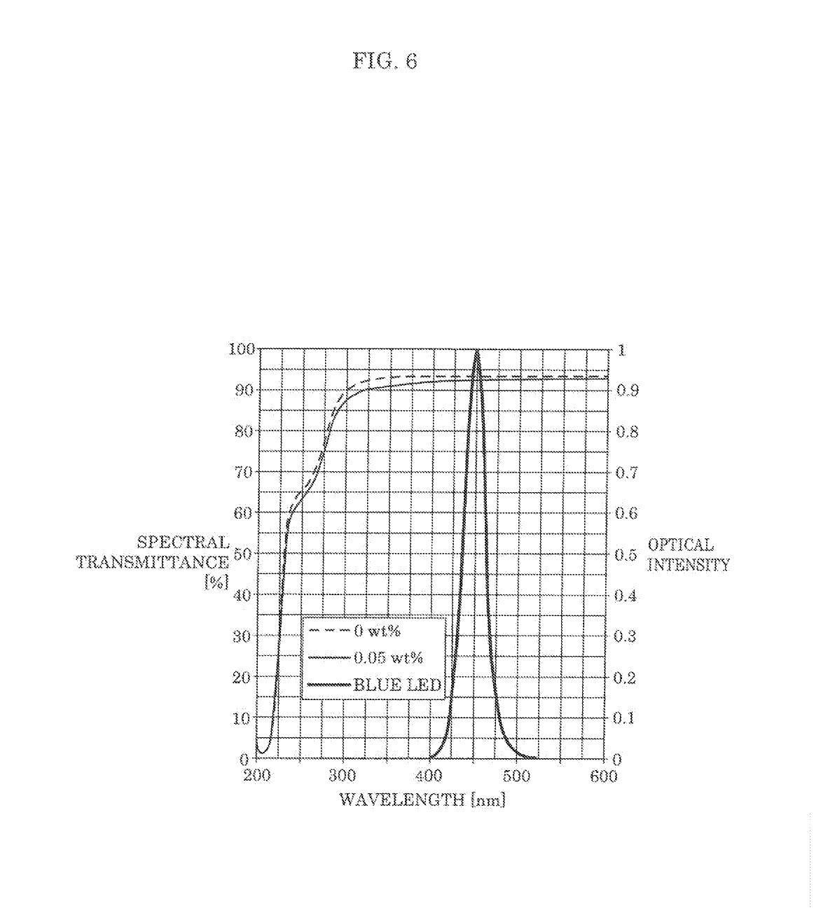

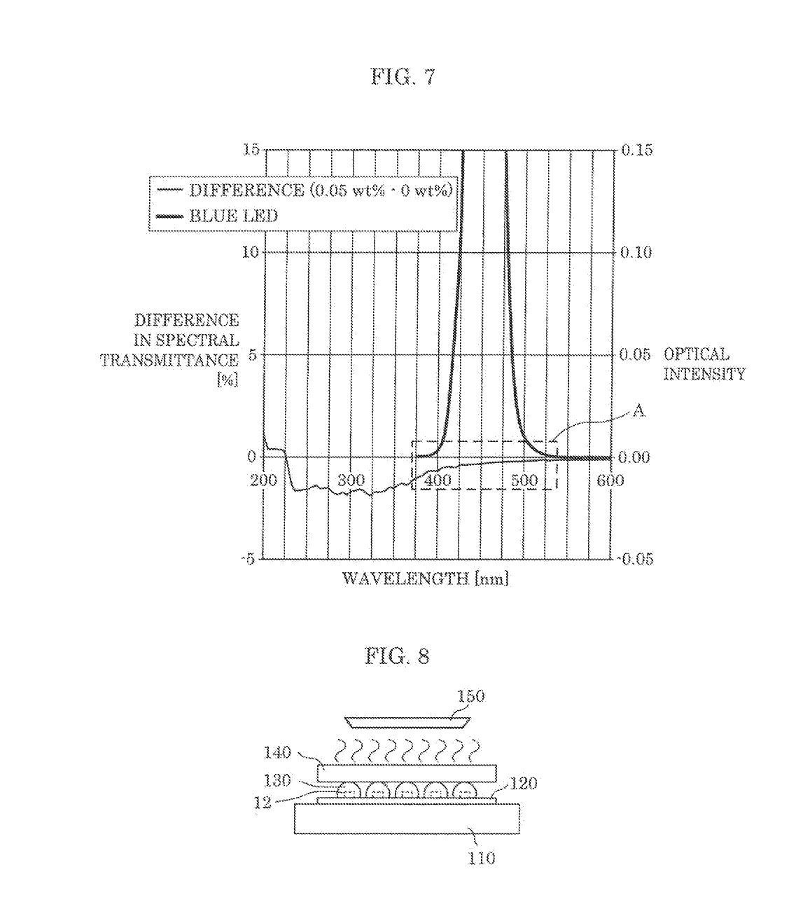

FIG. 6 shows a spectral transmittance of a silicone resin not containing cerium oxide 19, a spectral transmittance of a silicone resin containing 0.05 wt % of cerium oxide 19, and a light emission spectrum of LED chip 12 having a center wavelength of 450 nm. FIG. 7 shows a difference between a spectral transmittance of a silicone resin containing 0.05 wt % of cerium oxide 19 and a spectral transmittance of a silicone resin not containing cerium oxide 19, and a light emission spectrum of LED chip 12 having a center wavelength of 450 nm. Note that the optical intensity of LED chip 12 in FIG. 6 and FIG. 7 is normalized optical intensity.

As illustrated in FIG. 6 and FIG. 7, the wavelength range of light that a silicone resin containing cerium oxide 19 absorbs reaches at least about 500 nm. Furthermore, a difference in the spectral transmittance determined by subtracting the spectral transmittance of a sealing member not containing cerium oxide 19 from the spectral transmittance of a sealing member containing 0.05 wt % of cerium oxide 19 relative to a silicone resin is a negative value at least in the range from 400 nm to 500 nm as illustrated in FIG. 7. This means that light having a wavelength in the range from 400 nm to 500 nm is absorbed by cerium oxide 19. Thus, at least a portion of the light emitted from LED chips 12 having a center wavelength of 450 nm is absorbed fey cerium oxide 19 as illustrated in region A surrounded by a dashed line in FIG. 7.

Although the silicone resin is given as an example of the resin member containing cerium oxide 19 in the above description, other resin members are considered to be able to produce the same or similar result. The same applies to the following experiment.

### Content of Cerium Oxide

Cerium oxide 19 absorbs the light emitted from LED chip 12 and generates heat. Therefore, if the amount of cerium oxide 19 contained in sealing member 13 is excessive, LED chips 12 may break down due to an increase in temperature. Furthermore, if sealing member 13 contains too much cerium oxide 19, light-emitting apparatus 10 has reduced light emission efficiency with a reduced transmittance of the light emitted from LED chip 12.

On the other hand, if the amount of cerium oxide 19 contained in sealing member 13 is small, there is a concern that the resultant effect of reducing the occurrence of oxidation and degradation of sealing member 13 will not be sufficient.

Thus, there is still room for consideration regarding the amount of cerium oxide 19 contained in sealing member 13. In view of this, the inventors conducted the following experiment in order to determine an appropriate content of cerium oxide 19. FIG. 8 is for illustrating an experimental environment.

As illustrated in FIG. 8, experimental light-emitting apparatus 120 is placed on heat sink 110 in the experiment. In experimental light-emitting apparatus 120, 12 light-emitting element lines in each of which 14 LED chips 12 are connected in series are connected in parallel. LED chips 12 are sealed with transparent silicone resin 130 not containing yellow phosphor 14 or cerium oxide 19.

Furthermore, resin plate 140 is placed on experimental light-emitting apparatus 120. Resin plate 140 is, specifically, a resin plate that uses, as a base material, a silicone resin to which particles of cerium oxide 19 have been added. The thickness of resin plate 140 is 2 mm. The particles of cerium oxide 19 used in this experiment are powders produced at 100° C. from a Needral B-10 solution (manufactured by Taki Chemical Co., Ltd.).

Thermo viewer 150 is provided above resin plate 140. Thermo viewer 150 is a thermometer that measures the temperature of the top surface of resin plate 140 contactlessly.

Under the experimental environment described above, a current of 2400 mA was supplied to experimental light-emitting apparatus 120 to cause experimental light-emitting apparatus 120 to emit light, and the temperature of resin plate 140 was measured 10 seconds after the start of light emission. Note that an increase in the temperature of resin plate 140 can be considered to represent an increase in the temperature of sealing member 13 containing cerium oxide 19 as simulated data. The experiment was conducted on two or more resin plates 140 containing different amounts of cerium oxide 19.

In the experiment, the transmittance of light having a wavelength of 400 nm through resin plate 140 and the thermal resistance of resin plate 140 were also measured in addition to the temperature of resin plate 140. The thermal resistance of resin plate 140 is determined by whether or not resin plate 140 cracks after being left 96 hours at an ambient temperature of 260° C. (in DN43H which is a constant temperature oven manufactured by Yamato Scientific Co., Ltd.). When resin plate 140 does not crack, it is determined that there is no problem with the thermal resistance, and the occurrence of oxidation and degradation of resin plate 140 has been reduced. The thickness of resin plate 140 subjected to the measurement for cracks is 3 mm, which is different from that in the other measurement.

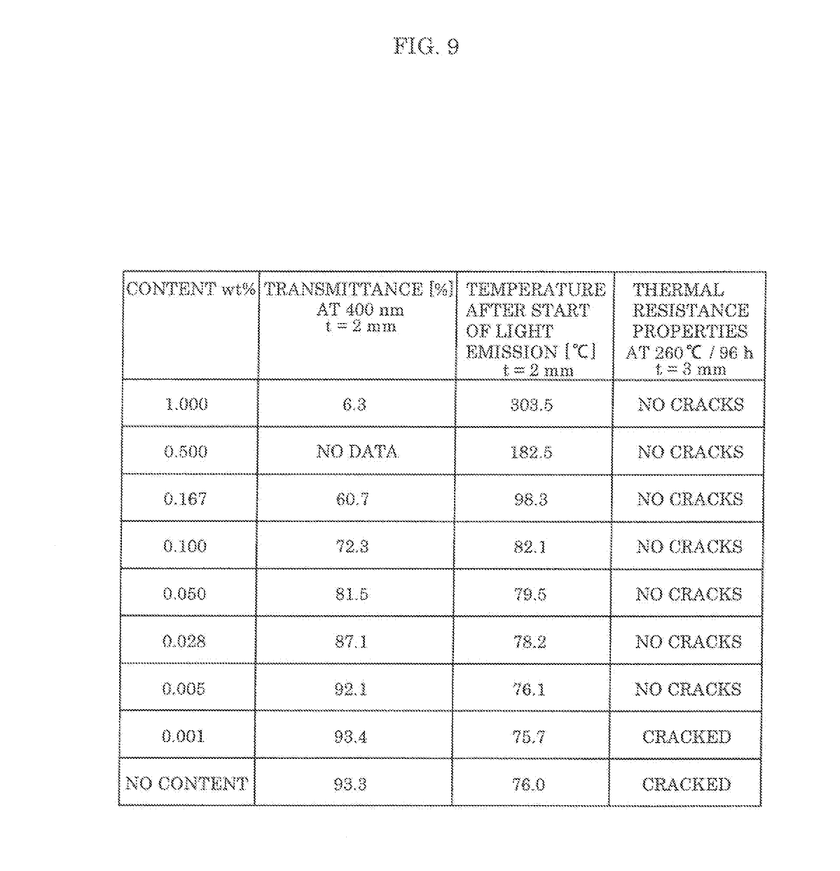

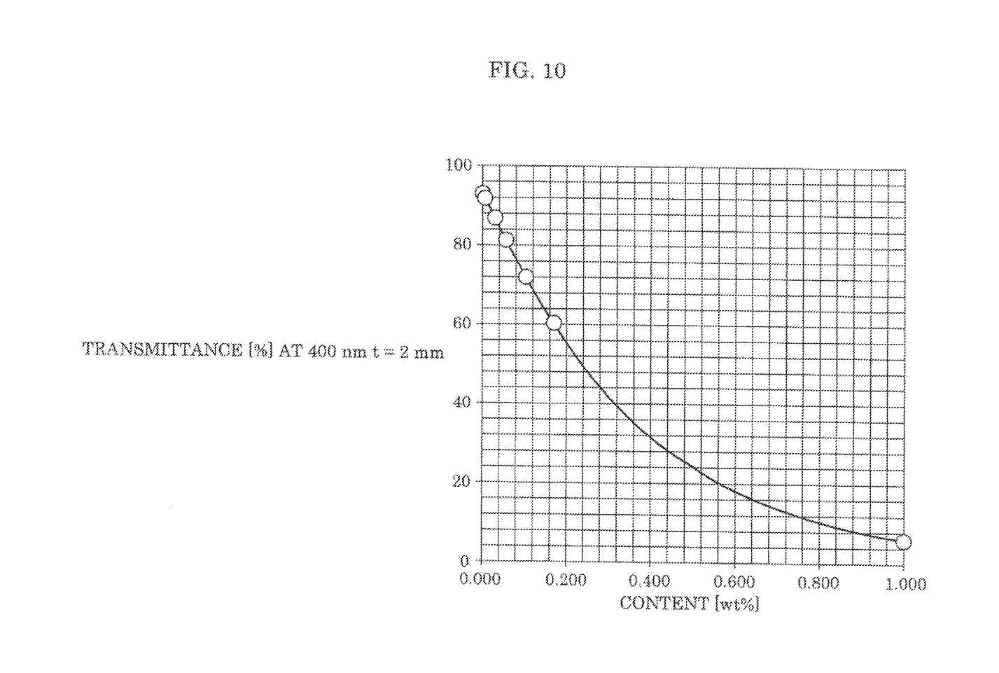

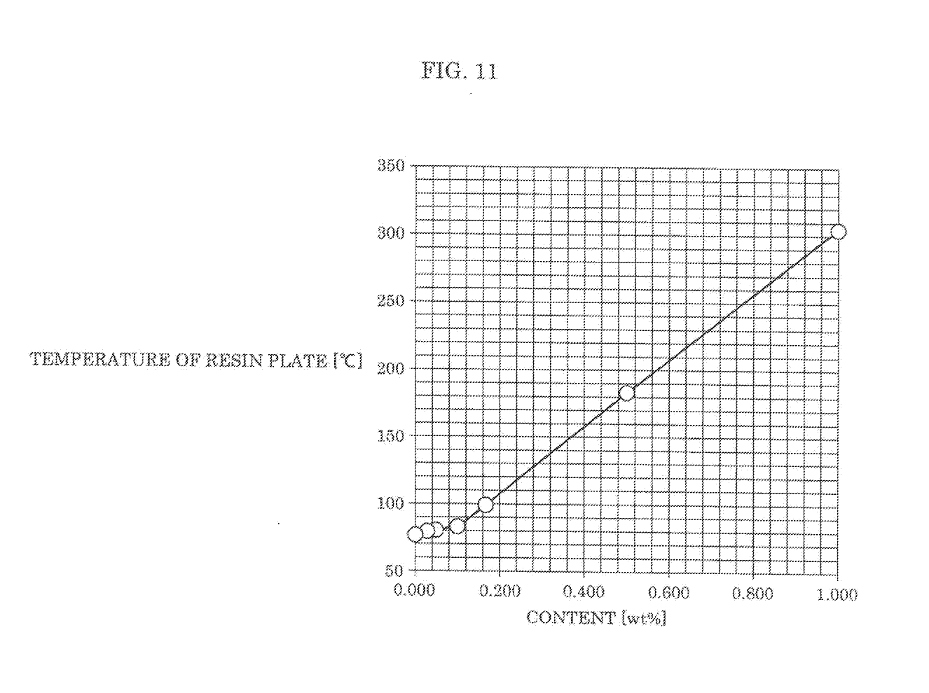

FIG. 9 illustrates the results of the above experiment FIG. 10 illustrates the relationship between the contact of cerium oxide 19 and the light transmittance of resin plate 140 among the experimental results in FIG. 9. FIG. 11 illustrates the relationship between the content of cerium oxide 19 and the temperature of resin plate 140 among the experimental results in FIG. 9.

First, the transmittance of light having a wavelength of 400 nm is described. As illustrated in FIG. 9 and FIG. 10, the transmittance of light having a wavelength of 400 nm through resin plate 140 is 6.3% when the content of cerium oxide 19 in resin plate 140 is 1.000 wt %. Likewise, the transmittance of light having a wavelength of 400 nm is 60.7% when the content of cerium oxide 19 is 0.167 wt %, and the transmittance of light having a wavelength of 400 nm is 72.3% when the content of cerium oxide 19 is 0.100 wt %.

The transmittance of light having a wavelength of 400 nm is 81.5% when the content of cerium oxide 19 is 0.050 wt %, and the transmittance of light having a wavelength of 400 nm is 87.1% when the content of cerium oxide 19 is 0.028 wt %. The transmittance of light having a wavelength of 400 nm is 92.1% when the content of cerium oxide 19 is 0.005 wt %, and the transmittance of light having a wavelength of 400 nm is 93.4% when the content of cerium oxide 19 is 0.001 wt %. The transmittance of light having a wavelength of 400 nm is 93.3% when the content of cerium oxide 19 is 0.000 wt % (no content).

Thus, as the content of cerium oxide 19 increases, the transmittance of light having a wavelength of 400 nm is reduced.

As described above, LED chip 12 has a peak wavelength of the light emission spectrum in the range from 430 nm to 470 nm and emits blue light. The transmittance of light having a wavelength of 400 nm through LED chip 12 just described is ideally at least about 70%. Accordingly, in light-emitting apparatus 10 including LED chips 12, the amount of cerium oxide 19 contained in sealing member 13 is ideally 0.100 wt % or less. The amount of cerium oxide 19 contained in sealing member 13 is more preferably 0.050 wt % or less so that the transmittance of light having a wavelength of 400 nm cannot be less than 80%.

As compared to light-emitting apparatus 10 including LED chips 12, light-emitting apparatus 10 including violet LED chips which have a peak wavelength of the light emission spectrum in the range from 365 nm to 425 nm and emit violet light is more affected by the transmittance of light having a wavelength of 400 nm (such as a reduction in the light emission efficiency of light-emitting apparatus 10). Accordingly, in light-emitting apparatus 10 including violet LED chips, the transmittance of light having a wavelength of 400 nm is ideally at least about 80%, and the amount of cerium oxide 19 contained in sealing member 13 is ideally 0.050 wt % or less. The amount of cerium oxide 19 contained in sealing member 13 is more preferably 0.030 wt % or less so that the transmittance of light having a wavelength of 400 nm cannot be less than 85%.

Next, the temperature of resin plate 140 measured 10 seconds after the start of light emission of experimental light-emitting apparatus 120 is described. As illustrated in FIG. 9 and FIG. 11, the temperature of resin plate 140 measured 10 seconds after the start of light emission of experimental light-emitting apparatus 120 is 303.5° C. when the amount of cerium oxide 19 contained in sealing member 140 is 1.000 wt %. When the amount of cerium oxide 19 contained in sealing member 140 is 0.500 wt %, the temperature of resin plate 140 measured 10 seconds after the start of light emission of experimental light-emitting apparatus 120 is 182.5° C.

Likewise, the temperature of resin plate 140 is 98.3° C. when the content of cerium oxide 19 is 0.167 wt %, and the temperature of resin plate 140 is 82.1° C. when the content of cerium oxide 19 is 0.100 wt %. The temperature of resin plate 140 is 79.5° C. when the content of cerium oxide 19 is 0.050 wt %, and the temperature of resin plate 140 is 78.2° C. when the content of cerium oxide 19 is 0.028 wt %. The temperature of resin plate 140 is 76.1° C. when the content of cerium oxide 18 is 0.005 wt %, and the temperature of resin plate 140 is 75.7° C. when the content of cerium oxide 19 is 0.001 wt %. The temperature of resin plate 140 is 76.0° C. when the content of cerium oxide 19 is 0.000 wt % (no content).

Thus, as the content of cerium oxide 19 increases, the increase in the temperature of resin plate 140 measured when LED chip 12 emits light increases. As illustrated in FIG. 11, an increase rate of the temperature of resin plate 140 with respect to an increase in the content of cerium oxide 19 (the slope of the graph in FIG. 11) is considered to be small when the content of cerium oxide 19 is less than or equal to 0.100 wt %. Therefore, the content of cerium oxide 19 is preferably 0.100 wt % or less from the perspective of reducing the increase in temperature.

Note that as compared to the light emitted from LED chip 12, a higher percentage of the light emitted from the violet LED chip having a peak wavelength of the light emission spectrum in the range from 365 nm to 425 nm is absorbed by cerium oxide 19, and the violet LED chip generates a larger amount of heat. Therefore, in light-emitting apparatus 10 including the violet LED, the amount of cerium oxide 19 contained in sealing member 13 is more preferably less than or equal to 0.050 wt %, which is less than 0.100 wt %. In light-emitting apparatus 10 including the violet LED, the amount of cerium oxide 19 contained in sealing member 13 is still more preferably less than or equal to 0.030 wt %.

Next, the presence or absence of a crack which represents the thermal resistance of sealing member 13 is described. When the amount of cerium oxide 19 contained in resin plate 140 is 1.000 wt %, 0.500 wt %, 0-167 wt %, 0.100 wt %, 0.050 wt %, 0.028 wt %, and 0.005%, resin plate 140 does not crack even after being stored in a high temperature environment. When the amount of cerium oxide 19 contained in resin plate 140 is 0.001 wt % and 0.000 wt % (no content), resin plate 140 cracks after being stored in a high-temperature environment.

Thus, the thermal resistance of resin plate 140 is reduced when the content of cerium oxide 19 is small. The same tendency is seen in the oxidation and degradation of resin plate 140; therefore, the content of cerium oxide 19 is preferably more than 0.001 wt % (more than or equal to 0.005 wt %) from the perspective of reducing the occurrence of oxidation and degradation of the silicone resin.

The foregoing has described the results of the experiment. In light-emitting apparatus 10, the light transmittance and the increase in temperature are taken into account on the basis of the above experimental results, and the amount of cerium oxide 19 to be contained in sealing member 13 is set to 0.100 wt % or less when the peak wavelength of the light emission spectrum of LED chip 12 is 470 nm or less.

### Advantageous Effects, Etc.

Light-emitting apparatus 10 includes substrate 11, LED chip 12 disposed on substrate 11, and sealing member 13 which contains yellow phosphor 14 and cerium oxide 19, and seals LED chip 12. The amount of cerium oxide 19 contained in sealing member 13 depends on a peak wavelength of a light emission spectrum of LED chip 12; when the peak wavelength of the light emission spectrum of LED chip 12 is 470 nm or less, the amount of cerium oxide 19 contained in sealing member 13 is 0.100 wt % or less.

Thus, the content of cerium oxide 19 in sealing member 13 is limited according to the peak wavelength of the light emission spectrum of LED chip 12 in light-emitting apparatus 10. Accordingly, it is possible to reduce the effect heat generated by cerium oxide 19 contained in sealing member 13 has on LED chip 12. Additionally, the reduction in the light transmittance of sealing member 13 is reduced, and thus the reduction in the light emission efficiency of light-emitting apparatus 10 is reduced.

Furthermore, when LED chip 12 emits blue light, the amount of cerium oxide 19 contained in sealing member 13 may be 0.100 wt % or less.

This allows light-emitting apparatus 10 to reduce the effect heat generated by cerium oxide 10 contained in sealing member 13 has on LED chip 12 that emits blue light. Furthermore, the reduction in the light transmittance of sealing member 13 is reduced, and thus the reduction in the light emission efficiency of light-emitting apparatus 10 is reduced. As illustrated in FIG. 9 and FIG. 10, the transmittance of light having a wavelength of 400 nm through sealing member 13 is ensured to be more than or equal to 70% when the base material of sealing member 13 is a silicone resin.

Furthermore, when LED chip 12 emits blue light, the amount of cerium oxide 19 contained in sealing member 13 may be 0.050 wt % or less.

With this, it is possible to further reduce the effect heat generated by cerium oxide 19 contained in sealing member 13 has on LED chip 12 that emits blue light. Furthermore, the reduction in the light transmittance of sealing member 13 is reduced, and thus the reduction in the light emission efficiency of light-emitting apparatus 10 is further reduced. As illustrated in FIG. 9 and FIG. 10, the transmittance of light having a wavelength of 400 nm through sealing member 13 is ensured to be more than or equal to 80% when the base material of sealing member 13 is a silicone resin.

Furthermore, the peak wavelength of the light emission spectrum of LED chip 12 is specifically in the range from 430 nm to 470 nm.

This allows light-emitting apparatus 10 to reduce the effect heat generated by cerium oxide 19 contained in sealing member 13 has on LED chip 12 having a peak wavelength of a light emission spectrum in the range from 430 nm to 470 nm. In addition, it is possible to reduce the reduction in the light emission efficiency of light-emitting apparatus 10 that includes LED chip 12 having a peak wavelength of a light emission spectrum in the range from 430 nm to 470 nm.

Furthermore, when LED chip 12 emits violet light, the amount of cerium oxide 19 contained in sealing member 13 may be 0.050 wt % or less.

This allows light-emitting apparatus 10 to reduce the effect heat generated by cerium oxide 19 contained in sealing member 13 has on LED chip 12 that emits violet light. Furthermore, the reduction in the light transmittance of sealing member 13 is reduced, and thus the reduction in the light emission efficiency of light-emitting apparatus 10 is reduced. As illustrated, in FIG. 9 and FIG. 10, the transmittance of light having a wavelength of 400 nm through sealing member 13 is ensured to be more than or equal to 80% when the base material of sealing member 13 is a silicone resin.

Furthermore when LED chip 12 emits violet light, the amount of cerium oxide 19 contained in sealing member 13 may be 0.030 wt % or less.

With this, it is possible to further reduce the effect heat generated by cerium oxide 19 contained in sealing member 13 has on LED chip 12 that emits violet light. Furthermore, the reduction in the light transmittance of sealing member 13 is reduced, and thus the reduction in the light emission efficiency of light-emitting apparatus 10 including LED chip 12 that emits violet light is reduced. As illustrated in FIG. 9 and FIG. 10, the transmittance of light having a wavelength of 400 nm through sealing member 13 is ensured to be more than or equal to 85% when the base material of sealing member 13 is a silicone resin.

Specifically, LED chip 12 that emits violet light (a violet LED chip) has a peak wavelength of a light emission spectrum in the range from 385 nm to 425 nm.

This allows light-emitting apparatus 10 to reduce the effect heat generated by cerium oxide 19 contained in sealing member 13 has on LED chip 12 that has a peak wavelength of a light emission spectrum in the range from 385 nm to 425 nm. In addition, it is possible to reduce the reduction in the light emission efficiency of light-emitting apparatus 10 that includes LED chip 12 having a peak wavelength of a light emission spectrum in the range from 365 nm to 425 nm.

Furthermore, the amount of cerium oxide 19 contained in sealing member 13 may be 0.005 wt % or more.

With this, it is possible to produce an advantageous effect of a reduction in the risk of cracking (an advantageous effect of a redaction in the occurrence of oxidation and degradation) even in a high-temperature environment as illustrated in FIG. 9.

### Embodiment 2

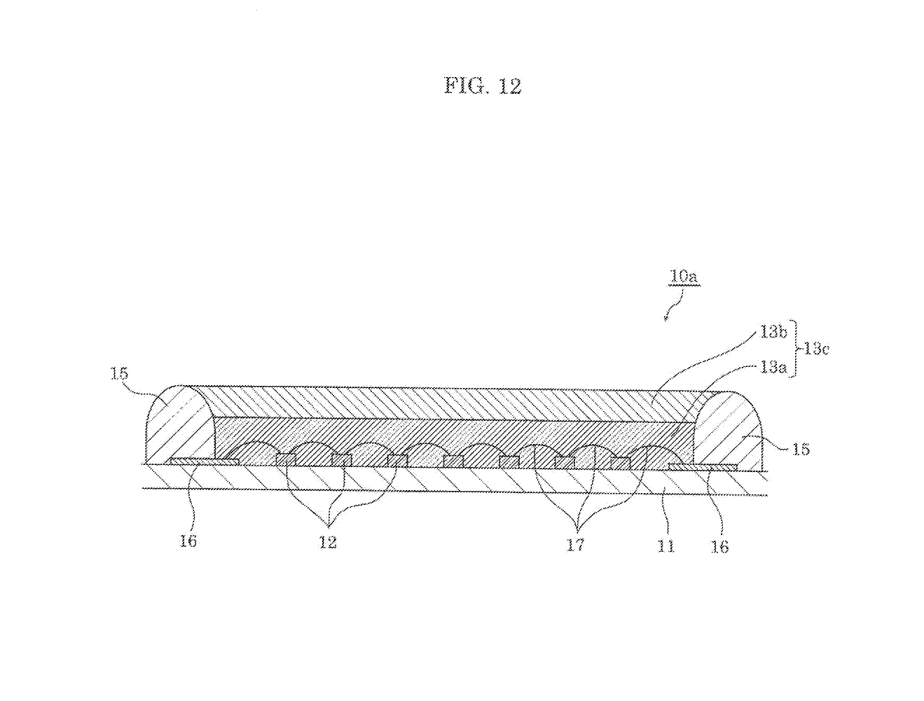

The following describes a light-emitting apparatus according to Embodiment 2. The light-emitting apparatus according to Embodiment 2 is the same in configuration as light-emitting apparatus 10 according to Embodiment 1, except for the sealing member; therefore, the following description will focus on the configuration of the sealing member with reference to a cross-sectional view. Elements that are substantially identical to those of light-emitting apparatus 10 are assigned the same reference signs, and descriptions thereof are omitted. FIG 12 is a cross-sectional view of a light-emitting apparatus according to Embodiment 2. Note that FIG. 12 is a cross-sectional view corresponding to a cross-section along line IV-IV in FIG. 2.

Light-emitting apparatus 10a according to Embodiment 2 is characterized in that sealing member 13c has a two-layered structure. Specifically, sealing member 13c includes first sealing layer 13a and second sealing layer 13b.

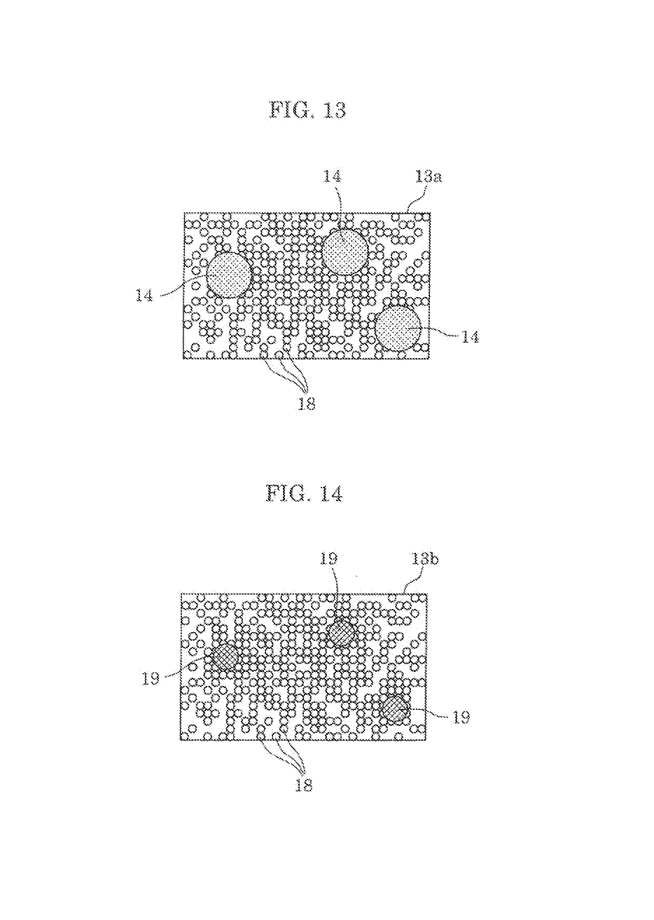

First, first sealing layer 13a is described with reference to FIG. 13 as well. FIG. 13 schematically illustrates a structure of first sealing layer 13a. Note that FIG. 13 is a schematic illustration; the shapes, grain sizes, etc., of yellow phosphor 14 and filler 18 illustrated in the figure are not precise.

First sealing layer 13a is a sealing layer that seals LED chips 12. As illustrated in FIG. 13, first sealing layer 13a is made of a light-transmissive resin material containing yellow phosphor 14 and filler 18, and does not contain cerium oxide 19. The light-transmissive resin material may be, for example, a silicone resin, but may be a phenol resin, an epoxy resin, a BT (bismaleimide-triazine) resin, PPA (polyphthalamide), or the like.

In first sealing layer 13a, yellow phosphor 14 less easily sinks due to filler 18 serving as a resistor. Therefore, yellow phosphor 14 is dispersed in first sealing layer 13a.

Note that filler 18 is not required to be contained in first sealing layer 13a. Furthermore, cerium oxide 19 may be contained in first sealing layer 13a. In this case, the amount of cerium oxide 19 contained in first sealing layer 13a is smaller than the amount of cerium oxide 19 contained in second sealing layer 13b.

First sealing layer 13a seals bonding wire 17 in addition to LED chips 12. This means that first sealing layer 13a has a function of protecting LED chips 12 and bonding wire 17 from dust, moisture, external force, or the like.

Furthermore, first sealing layer 13a functions also as a wavelength converting element, and the wavelength of a portion of the blue light emitted from LED chips 12 is converted by yellow phosphor 14 contained in first sealing layer 13a, so that the portion is transformed into yellow light. Then, the blue light not absorbed by yellow phosphor 14 and the yellow light resulting from the wavelength conversion by yellow phosphor 14 are diffused and mixed within first sealing layer 13a. Consequently, white light is emitted from first sealing layer 13a (sealing member 13c).

Next, second sealing layer 13b is described with reference to FIG. 14 as well. FIG. 14 schematically illustrates a structure of second sealing layer 13b. Note that FIG. 14 is a schematic illustration; the shapes, grain sizes, etc., of cerium oxide 19 and filler 18 illustrated in the figure are not precise.

Second sealing layer 13b is a sealing layer provided above first sealing layer 13a, and covers first sealing layer 13a. As illustrated in FIG. 14, second sealing layer 13b is made of a light-transmissive resin material containing cerium oxide 19 and filler 18, and does not contain yellow phosphor 14. For example, the same light-transmissive resin material as that used as first sealing layer 13a is used as second sealing layer 13b. Specifically, the light-transmissive resin material may be a silicone resin, but may be a phenol resin, an epoxy resin, a BT (bismaleimide-triazine) resin, PPA (polyphthalamide), or the like.

In second sealing layer 13b, cerium oxide 19 less easily sinks due to filler 18 serving as a resistor. Therefore, cerium oxide 19 is dispersed in second sealing layer 13b. Note that filler 18 is not required to be contained in second sealing layer 13b. Furthermore, yellow phosphor 14 may be contained in second sealing layer 13b.

Second sealing layer 13b is a part of sealing member 13 that comes into contact with air, and functions as a protective layer that reduces the occurrence of oxidation and degradation of first sealing layer 13a.

### Method of Manufacturing Light-emitting Apparatus According to Embodiment 2

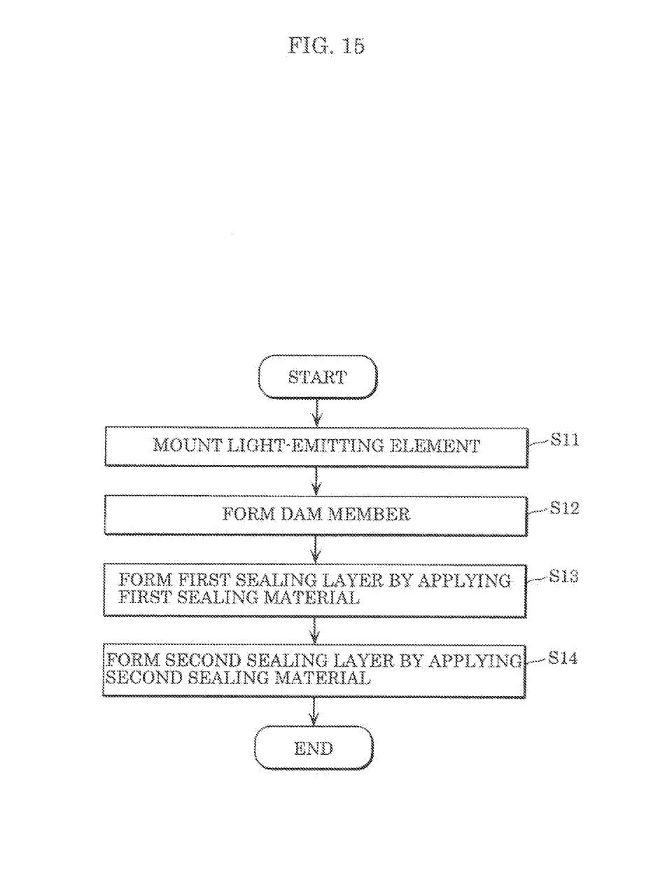

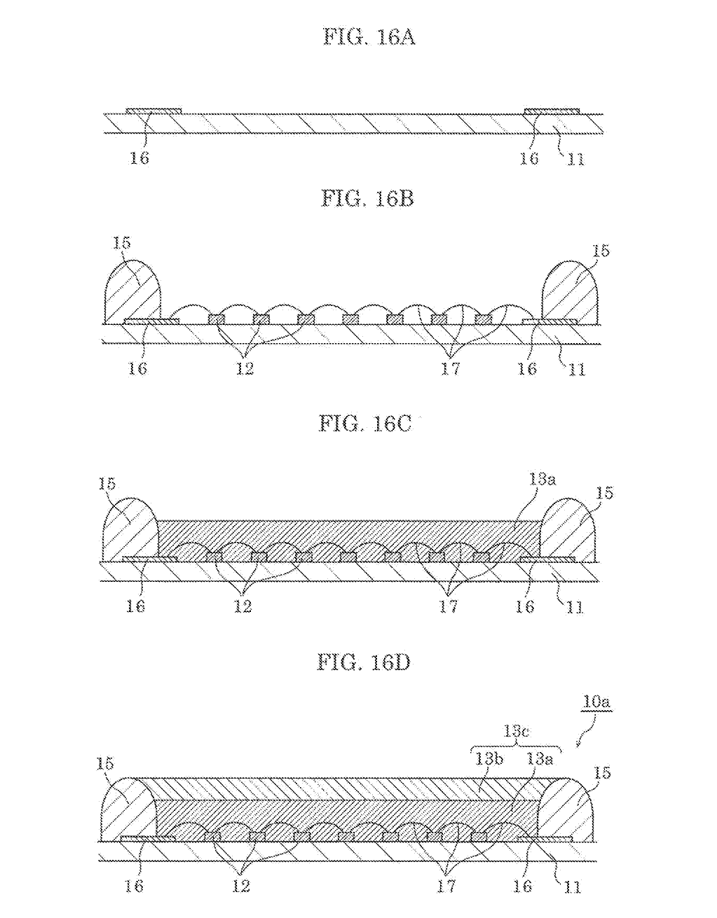

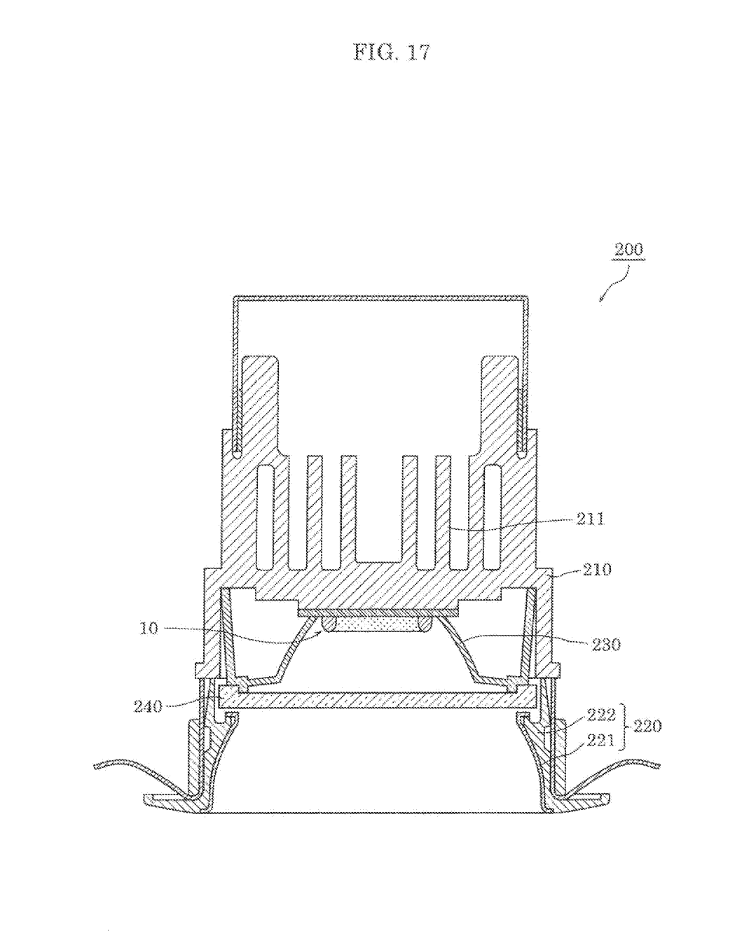

Next, a method of manufacturing light-emitting apparatus 10a is described. FIG. 15 is a flowchart of a method of manufacturing light-emitting apparatus 10a. FIG. 16A to FIG. 16D are schematic cross-sectional views illustrating a method of manufacturing light-emitting apparatus 10a. Note that FIG. 16A to FIG. 16D are cross-sectional views corresponding to a cross-section along line IV-IV in FIG. 2. The following manufacturing method and the size, etc., stated in the following description are one example.

First, two or more LED chips 12 are mounted on substrate 11 on which wiring 16 has been provided in advance as illustrated in FIG. 16A and FIG. 16B (S11). A die-attach material or the like is used to mount LED chips 12 by die bonding. At this time, two or more LED chips 12 are electrically connected to each other by bonding wire 17 and wiring 16. Note that the height of LED chips 12 is about 0.2 mm, and bonding wire 11 is about 0.15 mm above the top surface of LED chips 12.

Dam member 15 is then formed on the top surface of substrate 11 in a circular annular shape surrounding two or more LED chips 12 (S12). A dispenser that releases a white resin is used to form dam member 15. The height of dam member 15 is about 0.7 mm.

Next, first sealing layer 13a which seals LED chips 12 is formed as illustrated in FIG. 16C (S13). Specifically, a first sealing material which is a light-transmissive resin material containing yellow phosphor 14 and filler 18 is applied (poured) to the region surrounded by dam member 15. The thickness of first sealing layer 13a is in the range from about 0.5 mm to 0.6 mm.

Next, second sealing layer 13b is formed on first sealing layer 13a as illustrated in FIG. 16D (S14). Specifically, a second sealing material which is a light-transmissive resin material containing cerium oxide 19 and filler 18 is applied (poured) onto first sealing layer 13a. The light-transmissive resin material included in the second sealing material is the same as the light-transmissive resin material included in the first sealing material. The thickness of second sealing layer 13b is in the range from about 0.1 mm to 0.2 mm.

Lastly, entire sealing member 13c is cured by heating, light irradiation, or the like after Step S14.

Note that in Step S13, first sealing layer 13a may be cured, after which second sealing material is applied to form second sealing layer 13b. However, in this method, the light-transmissive resin material ends up with an interface between first sealing layer 13a and second sealing layer 13b, which may reduce the light extraction rate of light-emitting apparatus 10. Therefore, it is desirable that entire sealing member 13c be cured at the end as described above.

Although first sealing layer 13a and second sealing layer 13b are made of the same light-transmissive resin material in Embodiment 2, they may be formed of different resin materials. However, because of the advantage that the light-transmissive resin material will have no interface between first sealing layer 13a and second sealing layer 13b, it is desirable that first sealing layer 13a and second sealing layer 13b be formed of the same light-transmissive resin material and be cured after second sealing material is applied.

### Advantageous Effects, Etc.

Light-emitting apparatus 10a includes substrate 11, LED chip 12 disposed on substrate 11, and sealing member 13c which contains yellow phosphor 14 and cerium oxide 19, and seals LED chip 12. Sealing member 18c includes first sealing layer 13a which seals LED chip 12 and second sealing layer 13b provided above first sealing layer 13a. The amount of cerium oxide 19 contained in second sealing layer 13b is greater than the amount of cerium oxide 19 contained in first sealing layer 13a.

Thus, LED chip 12 is sealed with first sealing layer 13a which contains a small amount of cerium oxide 19, and second sealing layer 18b which contains a large amount of cerium oxide 19 is placed away from LED chip 12. Accordingly, the effect heat generated by cerium oxide 19 has on LED chip 12 is reduced more than in the case where cerium oxide 19 is contained evenly throughout the sealing member.

Furthermore, the oxidation and degradation of scaling member 13c would be prominent in a part thereof that comes into contact with air; however, in light-emitting apparatus 10a, a large amount of cerium oxide 19, which reduces the occurrence of oxidation and degradation, is contained in second sealing layer 13b of sealing member 13c which comes into contact with air. Therefore, the occurrence of oxidation and degradation of sealing member 13c can be efficiently reduced.

Furthermore, first sealing layer 13a is not required to contain cerium oxide 19.

Thus, LED chip 12 is sealed with first sealing layer 13a in which cerium oxide 19 is not contained, and second sealing layer 13b in which cerium oxide 19 is contained is placed away from LED chip 12. Accordingly, the effect heat generated by cerium oxide 19 has on LED chip 12 is reduced more than in the case where cerium oxide 19 is contained evenly throughout the sealing member.

Note that the stacked structure of sealing member 13c of light-emitting apparatus 10a is one example. This means that other stacked structures that can reduce the effect heat generated by cerium oxide 19 has on LED chip 12 are included in the present disclosure. For example, another layer may be provided between first sealing layer 13a and second seating layer 13b.

Furthermore, although examples of the main materials of each layer of the stacked structure of light-emitting apparatus 10a are listed in Embodiment 2, each layer of the stacked structure may contain other materials so long as the same or similar functions as light-emitting apparatus 10a described above can be obtained.

### Embodiment 3

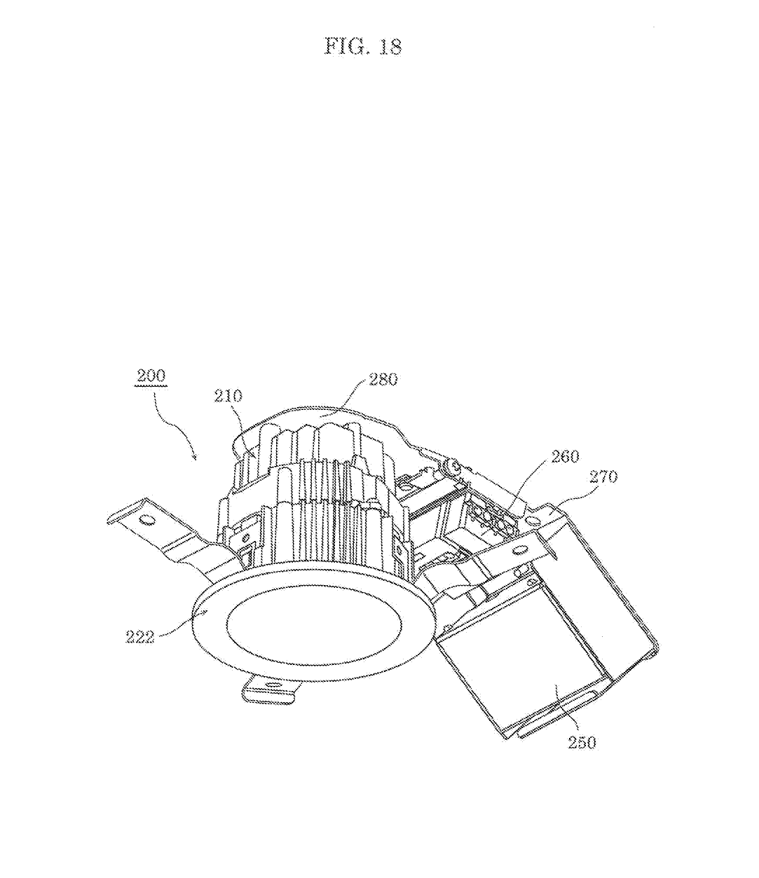

Next, illumination apparatus 200 according to Embodiment 3 is described with reference to FIG. 17 and FIG. 18. FIG. 17 is a cross-sectional view of illumination apparatus 200 according to Embodiment 3. FIG. 18 is a perspective view of external appearances of illumination apparatus 200 and peripheral members thereof according to Embodiment 3.

As illustrated in FIG. 17 and FIG. 18, illumination apparatus 200 according to Embodiment 3 is a sunken illumination apparatus, such as a recessed light, that emits light downward (toward the floor or a wall, for example) by being installed, for example, in the ceiling of a house.

Illumination apparatus 200 includes light-emitting apparatus 10. Illumination apparatus 200 further includes an apparatus body in the shape of a substantial bottomed tube formed by joining pedestal 210 and frame 220, and reflection plate 230 and light-transmissive panel 240 disposed on this apparatus body.

Pedestal 210 is an attachment base to which light-emitting apparatus 10 is attached, and also serves as a heat sink for dissipating heat generated by light-emitting apparatus 10. Pedestal 210 is formed into a substantially columnar shape using a metal material and is, in Embodiment 3, made of die-cast aluminum.

Two or more heat-dissipating fins 211 are provided at predetermined intervals along one direction on the top portion (ceiling-side portion) of pedestal 210 so as to protrude upward. With this, heat generated by light-emitting apparatus 10 can be efficiently dissipated.

Frame 220 includes: cone portion 221 including a reflective surface on an inner surface and having a substantially circular tube shape; and frame body 222 to which cone portion 221 is attached. Cone portion 221 is formed using a metal material and can, for example, be formed of an aluminum alloy or the like by metal spinning or pressing. Frame body 222 is formed of a hard resin material or a metal material. Frame 220 is fixed by frame body 222 being attached to pedestal 210.

Reflection plate 230 is a circular-annular-frame-shaped (funnel-shaped) reflection member having an inner surface reflection function. For example, reflection plate 230 can be formed using a metal material such as aluminum. Note that reflection plate 230 may be formed using a hard white resin material instead of a metal material.

Light-transmissive panel 240 is a light-transmissive member having light-diffusing properties and light-transmitting properties. Light-transmissive panel 240 is a flat plate disposed between reflection plate 230 and frame 220, and is attached to reflection plate 230. For example, light-transmissive panel 240 can be formed into a disc shape using a transparent resin material Such as acrylic or polycarbonate.

Note that illumination apparatus 200 is not required to include light-transmissive panel 240. Without light-transmissive panel 240, illumination apparatus 200 allows an improvement in the luminous flux of light that is emitted therefrom.

Furthermore, as illustrated in FIG. 18, lighting apparatus 250 which supplies light-emitting apparatus 10 with electric power for lighting light-emitting apparatus 10, and terminal base 260 which relays AC power from a commercial power supply to lighting apparatus 250 are connected to illumination apparatus 200. Specifically, lighting apparatus 250 converts AC power relayed by terminal base 260 into DC power, and outputs the DC power to light-emitting apparatus 10.

Lighting apparatus 250 and terminal base 260 are fixed to attachment plate 270 provided separately from the apparatus body. Attachment plate 270 is formed by folding a rectangular plate member made of a metal material, and has one longitudinal end the bottom surface of which lighting apparatus 250 is fixed to and the other longitudinal end she bottom surface of which terminal base 260 is fixed to. Attachment plate 270 is connected together with top plate 280 which is fixed to a top portion of pedestal 210 of the apparatus body.

As described above, illumination apparatus 200 includes light-emitting apparatus 10 and lighting apparatus 250 which supplies light-emitting apparatus 10 with electric power for lighting light-emitting apparatus 10. With this, the effect heat generated by cerium oxide 19 has on LED chip 12 can be reduced in illumination apparatus 200.

Note that illumination apparatus 200 may include light-emitting apparatus 10a instead of light-emitting apparatus 10. Also in this case, the effect heat generated by cerium oxide 19 has on LED chip 12 can be reduced in illumination apparatus 200.

Although the illumination apparatus is exemplified as a recessed light in Embodiment 3, the illumination apparatus according to the present disclosure may be implemented as a spotlight or a different illumination apparatus.

### OTHER EMBODIMENTS

Although the light-emitting apparatus and the illumination apparatus according to the embodiments have been described above, the present disclosure is not limited to the above-described embodiments.

For example, although the COB light-emitting apparatus has been described in the above embodiments, the present disclosure is applicable to a SMD (surface mount device) light-emitting apparatus as well. The SMD light-emitting apparatus (light-emitting element) includes, for example, a resin container having a cavity, an LED chip mounted in the cavity, and a sealing member (phosphor-containing resin) filling the cavity.

Moreover, in the above embodiments, the light-emitting apparatus emits white light using a combination of the LED chip that emits blue light or violet light with the yellow phosphor, but the configuration for emitting white light is not limited to that described above. For example, a phosphor-containing resin that contains a red phosphor and a green phosphor may be combined with an LED chip that emits blue light or violet light.

Furthermore, in the above embodiments, the LED chip mounted on the substrate is connected to another LED chip in a chip-to-chip configuration by a bonding wire. However, the LED chip may be connected by a bonding wire to wiring (a metal film) provided on the substrate, and thus electrically connected to another LED chip via the wiring.

Furthermore, the light-emitting element to be used in the light-emitting apparatus is exemplified as an LED chip in the above embodiments. However, a semiconductor light-emitting element, such as a semiconductor laser, or a solid-state light-emitting element including an organic or inorganic electroluminescence (EL) material may be used as the light-emitting element.

Furthermore, light-emitting elements of two or more types different in light-emission color may be used in the light-emitting apparatus. For example, with the aim of increasing color rendering properties, the light-emitting apparatus may include an LED chip that emits red light in addition to an LED chip that emits blue light or violet light.

While the foregoing has described what are considered to be the best mode and/or other examples, it is understood that various modifications may be made therein and that the subject matter disclosed herein may be implemented in various forms and examples, and that they may be applied in numerous applications, only some of which, have been described herein. It is intended by the following claims to claim any and all modifications and variations that fall within the true scope of the present teachings.

For example, in the light-emitting apparatus according to Embodiment 2, the amount of a cerium oxide contained in the sealing member may be defined as in the light-emitting apparatus according to Embodiment 1.

Furthermore, the light-emitting apparatus according to the present disclosure may be implemented as a method of manufacturing a light-emitting apparatus. For example, a method of manufacturing the light-emitting apparatus according to Embodiment 1 includes: mounting a light-emitting element on a substrate; adding a cerium oxide to a light transmissive resin material according to a peak wavelength of a light emission spectrum of the mounted light-emitting element; and sealing the mounted light-emitting element with the light-transmissive resin material to which the cerium oxide has been added.

What is claimed is:

1. A light-emitting apparatus comprising:
a substrate;
a light-emitting element disposed on the substrate; and
a sealing member that contains a phosphor and a cerium oxide, and seals the light-emitting element,
wherein an amount of the cerium oxide contained in the sealing member depends on a peak wavelength of a light emission spectrum of the light-emitting element, and
when the peak wavelength of the light emission spectrum of the light-emitting element is 470 nm or less, the amount of the cerium oxide contained in the sealing member is 0.100 wt % or less.

2. The light-emitting apparatus according to claim 1,
wherein the light-emitting element emits blue light.

3. The light-emitting apparatus according to claim 1,
wherein the light-emitting element emits blue light, and the amount of the cerium oxide contained in the sealing member is 0.050 wt % or less.

4. The light-emitting apparatus according to claim 2,
wherein the peak wavelength of the light emission spectrum of the light emitting element is in a range from 430 nm to 470 nm.

5. The light-emitting apparatus according to claim 1,
wherein the light-emitting element emits violet light, and the amount of the cerium oxide contained in the sealing member is 0.050 wt % or less.

6. The light-emitting apparatus according to claim 1,
wherein the light-emitting element emits violet light, the amount of the cerium oxide contained in the sealing member is 0.030 wt % or less.

7. The light-emitting apparatus according to claim 5,
wherein the peak wavelength of the light emission spectrum of the light emitting element is in a range from 365 nm to 425 nm.

8. The light-emitting apparatus according to claim 1,
wherein the amount of the cerium oxide contained in the sealing member is 0.005 wt % or more.

9. A light-emitting apparatus comprising:
a substrate;
a light-emitting element disposed on the substrate; and
a sealing member that contains a phosphor and a cerium oxide, and seals the light-emitting element,
wherein the sealing member includes:
a first sealing layer that seals the light-emitting element; and
a second sealing layer provided above the first sealing layer, and
an amount of the cerium oxide contained in the second sealing layer is greater than an amount of the cerium oxide contained in first sealing layer.

10. The light-emitting apparatus according to claim 9,
wherein the first sealing layer does not contain the cerium oxide.

11. An illumination apparatus comprising:
the light-emitting apparatus according to claim 1, and
a lighting apparatus that supplies the light-emitting apparatus with electric power for lighting the light-emitting apparatus.
